(19) United States
(12) Patent Application Publication
(10) Pub. No.: US 2015/0355233 A1
(43) Pub. Date: Dec. 10, 2015

(54) TEST SOCKET AND SOCKET BODY

(71) Applicant: ISC CO., LTD, Jungwon-gu, Seongnam-si, Gyeonggi-do (KR)

(72) Inventor: Jae Hak LEE, Seongnam-si (KR)

(73) Assignee: ISC CO., LTD., Seongnam-si, Gyeonggi-do (KR)

(21) Appl. No.: 14/655,905

(22) PCT Filed: Dec. 27, 2013
(86) PCT No.: PCT/KR2013/012257

§ 371 Date: Jun. 26, 2015

(30) Foreign Application Priority Data
Dec. 28, 2012 (KR) 10-2012-0157063

(51) Int. Cl. G01R 1/04; G01R 31/28

(52) U.S. Cl. CPC G01R 1/0433; G01R 31/2886

(57) ABSTRACT

The present invention relates to a test socket, and more specifically, to a test socket for electrically connecting a terminal of a test target device with a pad of a test device, comprising: a socket guide provided with a center hole at the center thereof so as to enable the terminal of the test target device to pass through and a guide protrusion provided to the lower surface thereof; and a socket body arranged between the socket guide and the test device, wherein the socket body comprises: a conductive region provided with a connection part arranged at a location corresponding to the terminal of the test target device so as to electrically connect the terminal of the test target device with the pad of the test device; and a supporting region for extending from a circumference of the conductive region and supporting the conductive region, and the supporting region comprises: a guide hole for receiving the guide protrusion so as to determine the location of the socket body with respect to the test device, and an elastic pressing part for elastically pressing the guide protrusion stored in the guide hole to one inner side surface of the guide hole.

### TECHNICAL FIELD

The inventive concept relates to a test socket and a socket body, and more particularly, to a test socket which enables a socket body to be easily aligned with a test device and the socket body.

### BACKGROUND ART

In general, a packaging operation is performed as the last operation for producing a semiconductor device, and before the packaging operation, a test process is performed to examine whether a semiconductor chip is normal or defective.

The semiconductor device testing process involves a manipulator who works in connection with a test device for testing electrical characteristics of the semiconductor device, handler equipment (not shown), and an insert guide for causing an insert member including therein the semiconductor device, which is a target object in contact with a socket installed on a board so that the electrical characteristics may be tested, to be accurately mounted on a socket.

FIG. 1 is an exploded view of an apparatus which tests a test-target device according to the related art, FIG. 2 is a combined view of FIG. 1, FIG. 3 is a top-down view of a test socket, and FIG. 4 is a diagram illustrating an example of operation of the apparatus according to the related art of FIG. 1.

The apparatus for a test according to the related art includes an insert 130 which moves toward a test device 150 while conveying a test-target device 140, such as a semiconductor device, and a test socket 100. The test socket 100 includes a socket body 110 which is mounted on the test device 150 and electrically connects terminals of the test-target device 140 and a pad of the test device 150 to each other, and a socket guide 120 which aligns the socket body 110 with the test device 150.

Meanwhile, the socket body 110 includes a conductive area 111 in which conductive parts 111a disposed at a position corresponding to the terminals of the test-target device 140 and electrically connecting the terminals of the test-target device 140 and the pad of the test device 150 to each other are prepared, and a frame 112 which supports the conductive area 111. In the frame 112, guide holes 112a which may align the position of the socket body 110 with guide protrusions 121 formed on the socket guide 120 is prepared.

When the socket guide 120 is combined with the test device 150, the guide protrusions 121 of the socket guide 120 are inserted into the guide holes 112a of the socket body 110, thereby aligning the position of the socket body 110. Here, the position is aligned so that the respective conductive parts 111a of the socket body 110 may be connected with the pad of the test device 150. After the position of the socket body 110 is aligned with the test device 150 in this way while the socket guide 120 is combined with the test device 150, the insert 130 descends and causes the terminals of the test-target device 140 to come in contact with the conductive parts 111a of the socket body 110. After the terminals of the test-target device 140 come in contact with the conductive parts 111a of the socket body 110 in this way, a predetermined electrical signal is applied from the test device 150 and transferred to the test-target device 140 via the conductive parts 111a so that a predetermined electrical test may be carried out.

In this electrical test, an accurate contact between the socket body 110 and the pad of the test device 150 or between the socket body 110 and the terminals of the test-target device 140 is required. In particular, a reduction in the distance (pitch) between the terminals of the test-target device 140 has lately increased the degree of precision of the socket body 110 compared to the past, and it is necessary to mount the socket body 110, which is manufactured with high precision in this way, at a precise position on the test device 150.

In order to precisely mount a socket body on a test device, a socket guide is used. In other words, as described above, predetermined guide holes are formed in the frame of the socket body, and guide protrusions are prepared on the socket guide and then inserted into the guide holes so that the position of the socket body is aligned.

However, due to the tolerance of such guide holes, there is a gap between each guide hole and a guide protrusion. In particular, as a pitch becomes finer, the gap, which was mostly insignificant, gradually becomes a more significant problem. Therefore, as shown in FIG. 4, conductive parts 111a of the socket body 110 mounted on the test device 150 do not accurately come in contact with the pad of the test device 150 or the terminals of the test-target device 140 so that a precise electrical test may not be carried out.

### DETAILED DESCRIPTION OF THE INVENTIVE CONCEPT

### Technical Problem

The inventive concept provides a test socket and a socket body which may be easily aligned with a test device.

### Technical Solution

According to an aspect of the inventive concept, there is provided a test socket for electrically connecting a terminal of a test-target device and a pad of a test device to each other, the test socket including a socket guide at a center of which a center hole is prepared so that the terminal of the test-target device passes through the socket guide, and on a lower surface of the socket guide a guide protrusion is prepared, and a socket body which is disposed between the socket guide and the test device. The socket body includes a conductive area in which a conductive part disposed at a position corresponding to the terminal of the test-target device and electrically connecting the terminal of the test-target device and the pad of the test device is prepared, and a support area which extends from an edge of the conductive area and supports the conductive area. The support area includes a guide hole which accommodates the guide protrusion so that a position of the socket body is determined with respect to the test device, and an elastic bias member which elastically biases the guide protrusion accommodated in the guide hole to one side in the guide hole.

In the test socket, the support area may include a plate formed of any one material from among stainless steel (SUS), polyimide, phosphor bronze, and beryllium copper.

In the test socket, the conductive part may include a silicone material in which a plurality of conductive metal particles are vertically aligned.

In the test socket, when a distance from a center of the guide hole to an inner surface of the guide hole is a first radius, at least a part of the elastic bias member may be inserted into a space encompassed by a first imaginary circle having the first radius and may come in contact with the guide protrusion.

In the test socket, the first radius of the guide hole may be larger than an external diameter of the guide protrusion by about 0.005 mm to about 0.025 mm.

In the test socket, a contacting surface of the elastic bias member coming in contact with the guide protrusion may have a circular arc shape.

In the test socket, the guide hole may have a circular arc shape, and an arc length of the guide hole may be larger than an arc length of the contacting surface.

In the test socket, the guide hole may have a circular arc shape, and an arc angle of the guide hole may be about 180° or more.

In the test socket, a curvature radius of the contacting surface may be larger than the first radius.

In the test socket, the curvature radius of the contacting may be larger than the first radius by about 0.05 mm to about 0.5 mm.

In the test socket, the elastic bias member may be spaced apart from surroundings of the guide hole by one pair of slots.

In the test socket, when the guide protrusion is inserted into the guide hole, the elastic bias member may be pressed by the guide protrusion in an insertion direction of the guide protrusion and elastically deformed.

According to another aspect of the inventive concept, there is provided a socket body whose position is determined by a socket guide at a center of which a center hole is prepared so that a terminal of a test-target device passes through the socket guide, and on a lower surface of the socket guide a guide protrusion is prepared, the socket body including a conductive area in which a conductive part disposed at a position corresponding to the terminal of the test-target device and electrically connecting the terminal of the test-target device and a pad of a test device is prepared, and a support area which extends from an edge of the conductive area and supports the conductive area. The support area includes a guide hole which accommodates the guide protrusion so that the position of the socket body is determined with respect to the test device, and an elastic bias member which elastically biases the guide protrusion accommodated in the guide hole to one side of the guide hole.

### ADVANTAGEOUS EFFECTS

According to the inventive concept, guide protrusions inserted into a socket body are placed at fixed positions in guide holes by elastic bias members in a support area, thereby enabling precise position alignment of a test socket and the socket body.

### DESCRIPTION OF THE DRAWINGS

FIG. 1 is an exploded view of an apparatus according to the related art.

FIG. 2 is a combined view of FIG. 1.

FIG. 3 is a top-down view of a test socket shown in FIG. 1.

FIG. 4 is a diagram illustrating an example of operation of the apparatus according to the related art of FIG. 1.

FIG. 5 is a top-down view of a socket body according to an embodiment of the present invention.

FIG. 6 is a partially enlarged view of FIG. 5.

FIG. 7 is a diagram showing a test-target device inserted into the socket body of FIG. 6.

FIG. 8 is a diagram showing a test carried out by using the socket body of FIG. 5.

FIGS. 9 and 10 are diagrams showing socket bodies according to other embodiments of the present invention.

### MODE OF THE INVENTIVE CONCEPT

Reference will now be made in detail to embodiments, examples of which are illustrated in the accompanying drawings, wherein like reference numerals refer to like elements throughout.

A test socket 10 according to an embodiment of the present invention is intended to electrically connect terminals 41 of a test-target device 40 and a pad 51 of a test device 50 to each other, and includes a socket guide and a socket body 30.

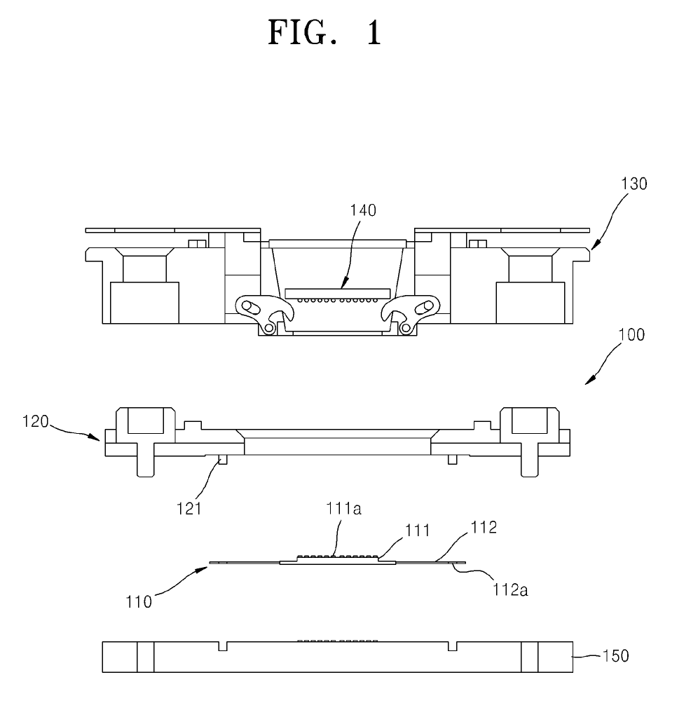

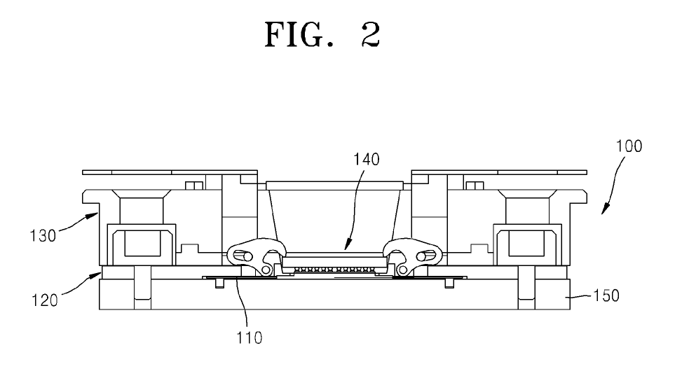

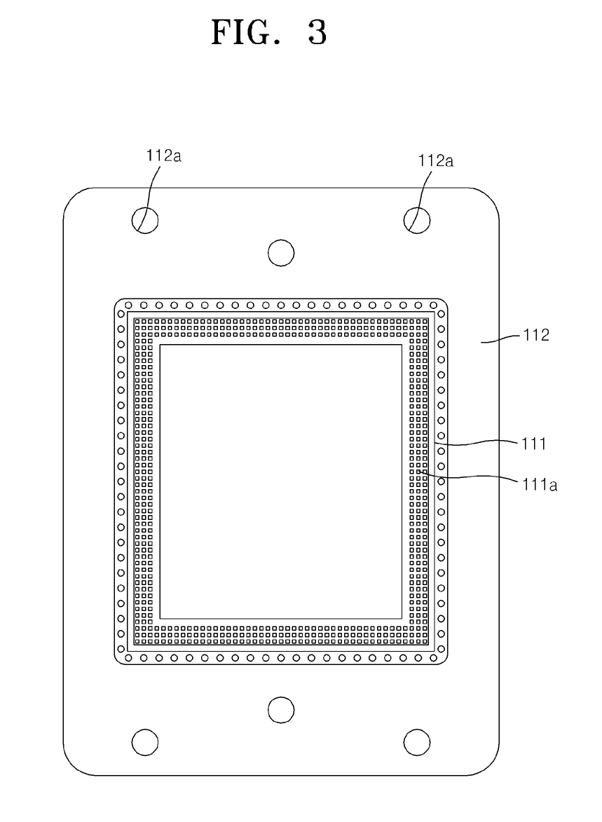

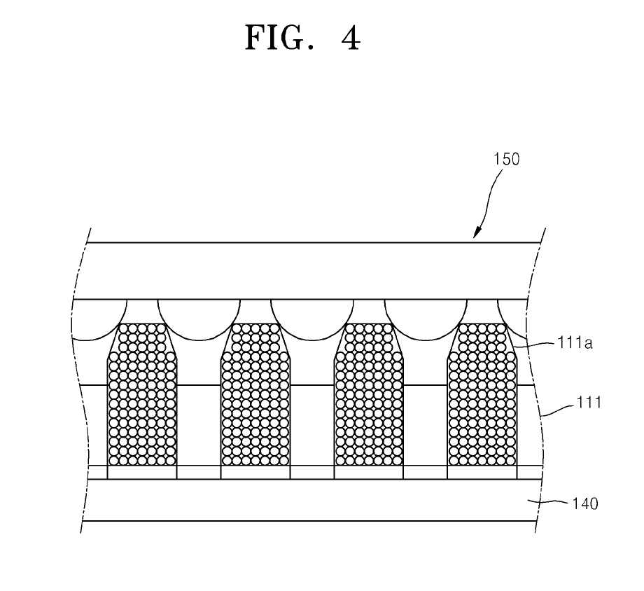

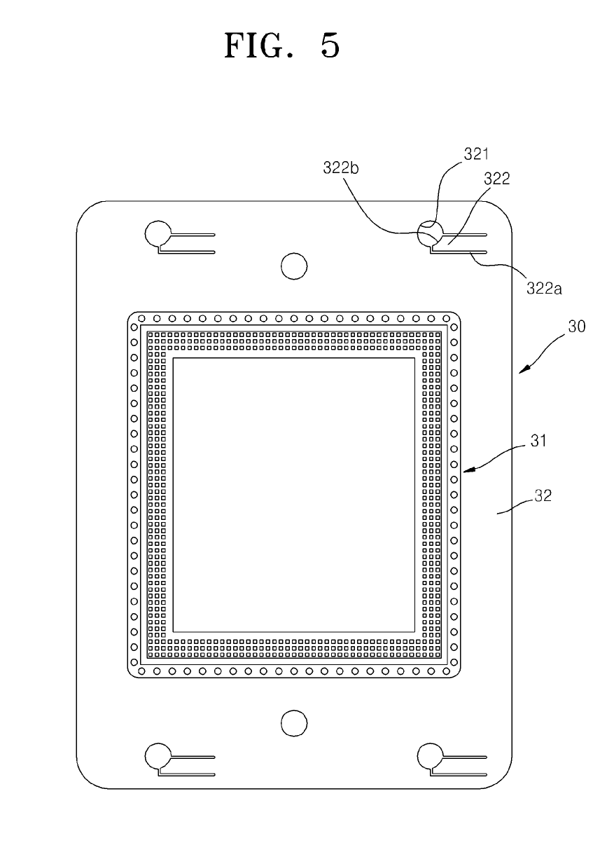

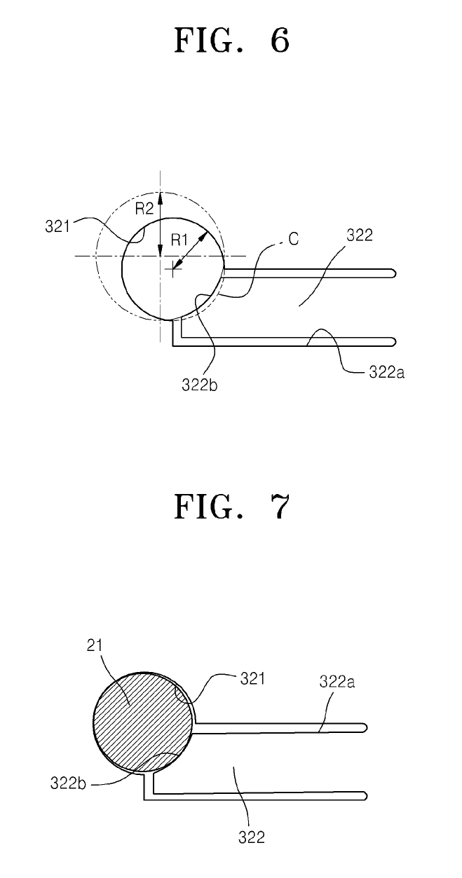

At the center of the socket guide (not shown), a center hole is prepared so that the terminals 41 of the test-target device 40 pass through the socket guide, and guide protrusions 21 are prepared on a lower surface of the socket guide. The socket guide has the same configuration as shown in FIG. 1, and a detailed description thereof will be omitted here.

The socket body 30 includes a conductive area 31 and a support area 32.

The conductive area 31 is disposed at a position corresponding to the terminals 41 of the test-target device 40, and a plurality of conductive parts 311 electrically connecting the terminals 41 of the test-target device 40 and the pad 51 of the test device 50 are prepared therein. The conductive area 31 may include the conductive parts 311 and an insulating part 312.

The conductive parts 311 are an elastic molecular material in which a plurality of conductive particles 311 a are vertically aligned. The upper ends of the conductive parts 311 may come in contact with the terminals 41 of the test-target device 40, and the lower ends thereof may come in contact with the pad 51 of the test device 50.

An elastomer constituting the conductive area 31 may be a polymer having a crosslinked structure. To obtain such an elastomer, various curable polymer-forming materials may be used. In particular, silicone rubber may be used in terms of molding and processing characteristics and electrical characteristics. The silicone rubber may be obtained by crosslinking or condensing liquid silicone rubber. The liquid silicone rubber may be any one of condensation-type liquid silicone, addition-type liquid silicone, liquid silicone rubber having vinyl groups or hydroxyl groups, and so on. For example, the liquid silicone rubber may be dimethyl silicone raw rubber, methylvinyl silicone raw rubber, methylphenylvinyl silicone, or so on.

A detailed example of the conductive particles 311a may be particles of a magnetic metal, such as iron, cobalt, nickel, etc., particles of an alloy of them, particles containing the metals, particles obtained by plating those particles as core particles with a metal having satisfactory conductivity, such as gold, silver, palladium, rhodium, etc., particles obtained by plating inorganic particles, such as non-magnetic metal particles, glass beads, etc., or polymer particles as core particles with a conductive magnetic material, such as nickel, cobalt, etc., particles obtained by coating core particles with both a conductive magnetic material and a metal having satisfactory conductivity, and so on. Among these, particles obtained by plating nickel particles as core particles with a metal, such as gold, silver, rhodium, palladium, ruthenium, tungsten, molybdenum, platinum, iridium, etc., are preferably used, or particles coated with a plurality of different metals, such as particles obtained by plating nickel particles with silver as base plating and then plating the surface layer with gold, are preferably used as well.

A method of coating core particles with a conductive metal is not particularly limited, and the coating may be performed through, for example, chemical plating or electroplating.

When particles obtained by coating core particles with a conductive material are used as the conductive particles 311a, a coating rate of the conductive material on particle surfaces (proportion of an area coated with the conductive metal to the surface area of the core particles) may be preferably about 40% or more to obtain satisfactory conductivity, more preferably about 45% or more, and particularly preferably about 47% to about 95%. Also, a coating amount of the conductive material may be preferably about 0.5 weight % to about 50 weight % of the core particles, more preferably about 2 weight % to about 30 weight %, further preferably about 3 weight % to about 25 weight %, and particularly preferably about 4 weight % to about 20 weight %. When the coating conductive metal is gold, a coating amount thereof may be about 0.5 weight % to about 30 weight %, more preferably about 2 weight % to about 20 weight %, further preferably about 3 weight % to about 15 weight %, and particularly preferably about 4 weight % to about 10 weight %. Also, when the coating conductive metal is silver, a coating amount thereof may be about 4 weight % to about 50 weight %, more preferably about 5 weight % to about 40 weight %, and further preferably about 10 weight % to about 30 weight %.

A particle diameter of the conductive particles 311a may be preferably about 1 μm to about 1000 μm, more preferably about 2 μm to about 500 μm, further preferably about 5 μm to about 300 μm, and particularly preferably about 10 μm to about 200 μm. Also, a particle diameter distribution (Dw/Dn) of the conductive particles 311a may be preferably about 1 to about 10, more preferably about 1.01 to about 7, further preferably about 1.05 to about 5, and particularly preferably about 1.1 to about 4. The conductive parts 311 obtained by using the conductive particles 311a which satisfy these conditions may be easily deformed by pressure, and the conductive particles 311a electrically come in contact with each other enough in the conductive parts 311. The conductive particles 311a are not limited to a particular shape, but may have a spherical shape, a star-like shape, or the shape of a lump of secondary particles of agglomerating spherical particles and star-like particles.

The insulating part 312 insulates each conductive part 311 while connecting the plurality of vertically extending conductive parts 311, and may be formed of silicone rubber.

The support area 32 extends from the edge of the conductive area 31 and supports the conductive area 31. The support area 32 may be a plate formed of any one material from among stainless steel (SUS), polyimide, phosphor bronze, and beryllium copper. The support area 32 may be formed of a material which has a hardness slightly higher than that of the conductive area 31 to support the conductive area 31.

The support area 32 may include guide holes 321 which accommodate the guide protrusions 21 so that the position of the socket body 30 is determined with respect to the test device 50, and elastic bias members 322 which elastically bias the guide protrusions 21 accommodated in the guide holes 321 to one side in the guide holes 321.

Each guide hole 321 may have an internal diameter which is larger than an external diameter of each guide protrusion 21 by about 0.01 mm to about 0.05 mm (about 0.005 mm to about 0.025 mm in radius). At least a part of the guide hole 321 is cut off, and the guide hole 321 has a circular arc shape. An arc angle θ of the guide hole 321 may be about 180° or more, and specifically about 270° to about 330°.

Each elastic bias member 322 is spaced apart from surroundings of the corresponding guide hole 321 by slots 322a, and at least a part thereof is included in the guide hole 321. When the distance from the center of the guide hole 321 to the inner surface of the guide hole 321 is a first radius R1, at least the part of the elastic bias member 322 may be inserted into a space encompassed by a first imaginary circle C having the first radius R1 and may come in contact with a guide protrusion 21. A contacting surface 322b of the elastic bias member 322 which comes in contact with the guide protrusion 21 may have a circular arc shape. A curvature radius R2 of the contacting surface 322b may be larger than the first radius R1. More specifically, the curvature radius R2 of the contacting surface 322b may be larger than the first radius R1 by about 0.05 mm to about 0.5 mm. Since the curvature radius R2 of the contacting surface 322b is larger than the first radius R1, the inserted guide protrusion 21 may not come in contact with an angulated portion but may come in contact with a rounded surface. Meanwhile, the arc length of the guide hole 321 may be larger than the arc length of the contacting surface 322b.

Accordingly, when the guide protrusion 21 is inserted into the guide hole 321, the elastic bias member 322 may be pressed by the guide protrusion 21 in the insertion direction of the guide protrusion 21 and elastically deformed. After the guide protrusion 21 is pulled out, the elastic bias member 322 may be elastically returned to its original position.

The test socket 10 and the socket body 30 according to the present embodiment have the following operational effects.

First, when a guide protrusion 21 of the socket guide is inserted into the corresponding guide hole 321 prepared in the support area 32 of the socket body 30, with the socket body 30 having been placed on the test device 50, the guide protrusion 21 comes in contact with the corresponding elastic bias member 322, at least a part of which protrudes in the guide hole 321, in the process of being inserted into the guide hole 321. The elastic bias member 322 which comes in contact with the guide protrusion 21 in this way is elastically deformed by insertion of the guide protrusion 21 and pushes the guide protrusion 21 to one side of the inner surface of the guide hole 321 (specifically, a surface facing the elastic bias member 322). When the guide protrusion 21 is pushed to the inner surface of the guide hole 321 in this way, the socket body 30 may be always placed at substantially the same position.

In other words, the elastic bias member 322 keeps biasing the guide protrusion 21 to the one side of the inner surface of the guide hole 321 which faces the elastic bias member 322, and thus the guide protrusion 21 may be placed at the fixed position in the guide hole 321 regardless of a position at which the guide protrusion 21 is inserted. Since the guide protrusion 21 may be placed at the fixed position in the guide hole 321 in this way, alignment of the socket body 30 may be ensured.

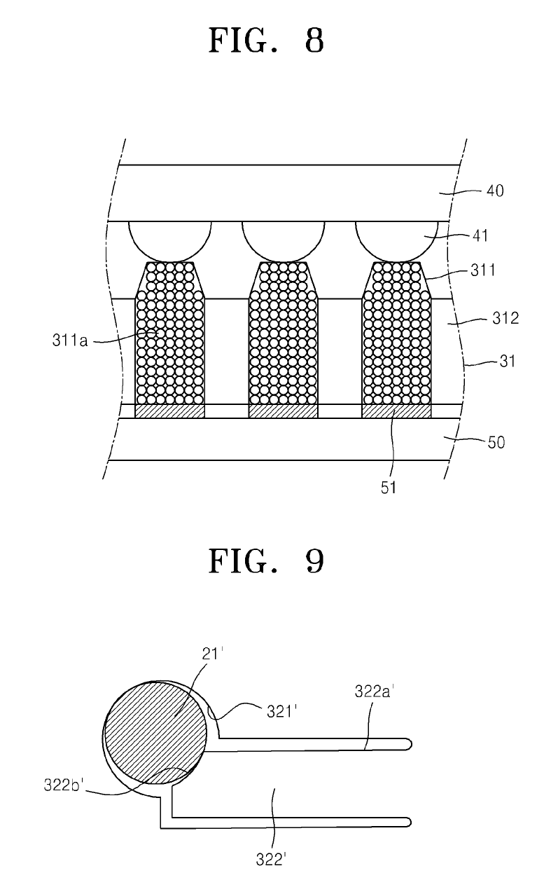

In this way, the position of the socket body 30 may always be uniformly aligned, and thus as shown in FIG. 8, a contact state between the conductive parts 311 of the socket body 30 and the pad 51 of the test device 50 or the terminals 41 of the test-target device 40 may be maintained as desired.

The test socket 10 according to the embodiment of the present invention may be modified as follows.

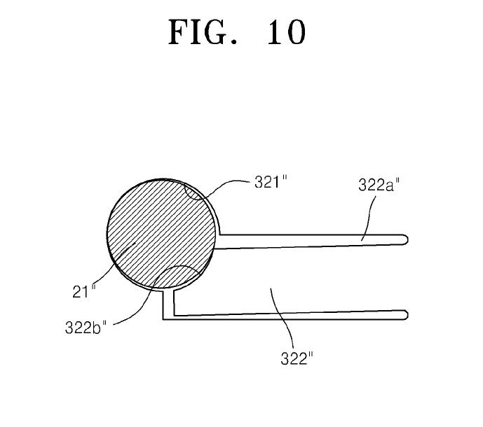

As shown in FIG. 9, in a socket body 30′, an elastic bias member 322′ may extend to a deep position inside a guide hole 321′. Also, as shown in FIG. 10, the curvature radius of an elastic bias member 322b″ may be smaller than the first radius R1. However, in this case, it is necessary to prevent an angulated portion of the elastic bias member 322b″ from coming in contact with a guide protrusion.

While the inventive concept has been particularly shown and described with reference to exemplary embodiments thereof, it will be understood that various changes in form and details may be made therein without departing from the spirit and scope of the following claims.

1. A test socket for electrically connecting a terminal of a test-target device and a pad of a test device to each other, the test socket comprising:
a socket guide at a center of which a center hole is prepared so that the terminal of the test-target device passes through the socket guide, and on a lower surface of the socket guide a guide protrusion is prepared; and
a socket body which is disposed between the socket guide and the test device,
wherein the socket body comprises:
a conductive area in which a conductive part disposed at a position corresponding to the terminal of the test-target device and electrically connecting the terminal of the test-target device and the pad of the test device is prepared; and
a support area which extends from an edge of the conductive area and supports the conductive area,
wherein the support area comprises:
a guide hole which accommodates the guide protrusion so that a position of the socket body is determined with respect to the test device; and
an elastic bias member which elastically biases the guide protrusion accommodated in the guide hole to one side in the guide hole.

2. The test socket of claim 1, wherein the support area comprises a plate formed of any one material from among stainless steel (SUS), polyimide, phosphor bronze, and beryllium copper.

3. The test socket of claim 1, wherein the conductive part comprises a silicone material in which a plurality of conductive metal particles are vertically aligned.

4. The test socket of claim 1, wherein, when a distance from a center of the guide hole to an inner surface of the guide hole is a first radius, at least a part of the elastic bias member is inserted into a space encompassed by a first imaginary circle having the first radius and comes in contact with the guide protrusion.

5. The test socket of claim 4, wherein the first radius of the guide hole is larger than an external diameter of the guide protrusion by about 0.005 mm to about 0.025 mm.

6. The test socket of claim 4, wherein a contacting surface of the elastic bias member coming in contact with the guide protrusion has a circular arc shape.

7. The test socket of claim 6, wherein the guide hole has a circular arc shape, and an arc length of the guide hole is larger than an arc length of the contacting surface.

8. The test socket of claim 6, wherein the guide hole has a circular arc shape, and an arc angle of the guide hole is about 180° or more.

9. The test socket of claim 6, wherein a curvature radius of the contacting surface is larger than the first radius.

10. The test socket of claim 9, wherein the curvature radius of the contacting surface is larger than the first radius by about 0.05 mm to about 0.5 mm.

11. The test socket of claim 1, wherein the elastic bias member is spaced apart from surroundings of the guide hole by one pair of slots.

12. The test socket of claim 11, wherein, when the guide protrusion is inserted into the guide hole, the elastic bias member is pressed by the guide protrusion in an insertion direction of the guide protrusion and elastically deformed.

13. A socket body whose position is determined by a socket guide at a center of which a center hole is prepared so that a terminal of a test-target device passes through the socket guide, and on a lower surface of the socket guide a guide protrusion is prepared, the socket body comprising:
a conductive area in which a conductive part disposed at a position corresponding to the terminal of the test-target device and electrically connecting the terminal of the test-target device and a pad of a test device is prepared; and
a support area which extends from an edge of the conductive area and supports the conductive area,
wherein the support area comprises:
a guide hole which accommodates the guide protrusion so that the position of the socket body is determined with respect to the test device; and
an elastic bias member which elastically biases the guide protrusion accommodated in the guide hole to one side of the guide hole.
